(19) United States
(12) Patent Application Publication
(10) Pub. No.: US 2025/0085637 A1
(43) Pub. Date: Mar. 13, 2025

(54) EXPOSURE MASK, SEMICONDUCTOR DEVICE USING THE EXPOSURE MASK, AND METHOD OF MANUFACTURING THE SEMICONDUCTOR DEVICE

(71) Applicant: SK hynix Inc., Icheon-si Gyeonggi-do (KR)

(72) Inventor: Jong Hoon KIM, Icheon-si Gyeonggi-do (KR)

(73) Assignee: SK hynix Inc., Icheon-si Gyeonggi-do (KR)

(21) Appl. No.: 18/587,218

(22) Filed: Feb. 26, 2024

(30) Foreign Application Priority Data
Sep. 13, 2023 (KR) 10-2023-0121600

(51) Int. Cl. G03F 7/20; H01L 21/027; H01L 21/033

(52) U.S. Cl. CPC G03F 7/2022; H01L 21/0274; H01L 21/0337

(57) ABSTRACT

An exposure mask for forming a pattern having a first width includes a first line, a second line, and at least one bridge line. The first line may be extended in a first direction. The first line has a second width narrower than the first width. The second line may be extended parallel to and spaced apart from the first line. The second line is formed having the second width. The bridge line may be connected between the first line and the second line.

### CROSS-REFERENCES TO RELATED APPLICATION

The present application claims priority under 35 U.S.C. § 119(a) to Korean application number 10-2023-0121600, filed on Sep. 13, 2023, in the Korean Intellectual Property Office, which is incorporated herein by reference in its entirety.

### BACKGROUND

### 1. Technical Field

Various embodiments generally relate to a semiconductor device, more particularly, to an exposure mask, a semiconductor device formed using the exposure mask, and a method of manufacturing the semiconductor device.

### 2. Related Art

In order to provide a semiconductor device with a high integration degree and a small size, an optical apparatus having a high resolution may be used to form a fine pattern on a substrate.

The optical apparatus having the high resolution may form the fine pattern having a target width.

The semiconductor device may include a region where a pattern having a first pitch may be formed and a region where a pattern having a second pitch wider than the first pitch may be formed. Thus, when patterns having various pitches are formed using an optical apparatus optimal to a specific region, a profile of the pattern may deteriorate due to a focus error in an exposure process.

### SUMMARY

According to example embodiments, there may be provided an exposure mask for forming a pattern having a first width. The exposure mask may include a first line, a second line and at least one bridge line. The first line may be extended in a first direction. The first line may have a second width narrower than the first width. The second line may be extended parallel to and spaced apart from the first line. The second line may have the second width. The bridge line may be connected between the first line and the second line.

According to example embodiments, there may be provided a semiconductor device. The semiconductor device may include a semiconductor substrate, a first target pattern, and a second target pattern. The semiconductor substrate may include a first region and a second region. The first target pattern may be formed in the first region. The first target pattern may have a second width extended in a first direction. The second target pattern may be formed in the second region. The second target pattern may have a first width wider than the second width. The second target pattern may include a first line, a second line, and at least one bridge line. The first line may be extended in the first direction. The first line may have the second width. The second line may be extended in the first direction. The second line may be spaced apart from the first line along a second direction different from the first direction. The second line may have the second width. The bridge line may be connected between the first line and the second line.

According to example embodiments, a semiconductor device is provided. The semiconductor device may include a lower structure, a first line, a second line, and a plurality of bridge lines. The lower structure may include a plurality of contacts arranged in a first direction. The first line may be extended in the first direction along a first side of the contacts over the lower structure. The first line may have a second width. The second line may be extended in the first direction along a second side of the contacts over the lower structure. The first side of the contacts may be located opposite to the second side of the contacts. The second line may be extended in the first direction. The second line may have the second width. The bridge lines may be connected between the first line and the second line. The bridge lines may contact first surfaces of the contacts thereby connecting the first line with the second line.

According to example embodiments, a method of manufacturing a semiconductor device is provided. In the method of manufacturing the semiconductor device, a semiconductor substrate may be provided comprising a first region and a second region. The semiconductor substrate may include a lower structure. A first target pattern may be formed on the lower structure in the first region. The first target pattern may have a second width narrower than a first width. A photoresist pattern may be formed on the lower structure in the second region using an exposure mask. The exposure mask may include a first line, a second line, and at least one bridge line. The first line may be extended in a first direction. The first line may have the second width. The second line may be extended parallel to and spaced apart from the first line. The second line may have the second width. The bridge line may be connected between the first line and the second line. A layer of the lower structure under the photoresist pattern may be patterned using the photoresist pattern to form a second target pattern having the first width.

According to example embodiments, a semiconductor device is provided. The semiconductor device may include a semiconductor substrate comprising a first region and a second region. A first target pattern may be formed having a first width in the first region. A plurality of spaced second target patterns may be formed in the second region, wherein each second target pattern may be formed having a second width. Each second target pattern may comprise a first line extended in a first direction, a second line spaced apart from the first line along a second direction different from the first direction, and at least one bridge line connected between the first line and the second line.

### BRIEF DESCRIPTION OF THE DRAWINGS

The above and another aspects, features, and advantages of the subject matter of the present disclosure will be more clearly understood from the following detailed description taken in conjunction with the accompanying drawings, in which:

FIG. 1A through FIG. 1C are views illustrating patterns by target widths in an optical apparatus having a high resolution;

FIG. 2 is a view illustrating an exposure mask in accordance with example embodiments;

FIG. 3 is a plan view illustrating a semiconductor device in accordance with example embodiments;

FIG. 4A through FIG. 4D illustrate cross-sectional views of a semiconductor device formed utilizing a method of manufacturing the semiconductor device in accordance with example embodiments; and

FIG. 5A through FIG. 5D illustrate plan views of a semiconductor device formed utilizing a method of manufacturing the semiconductor device in accordance with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes that do not depart from the spirit and scope of the present invention as set forth in the appended claims.

The present description references cross-section and/or plan illustrations of idealized embodiments. However, such embodiments should not be construed as limiting the inventive concept. Although a few embodiments will be shown and described, it will be appreciated by those of ordinary skill in the art that changes may be made in these embodiments without departing from the principles and spirit of the present invention.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

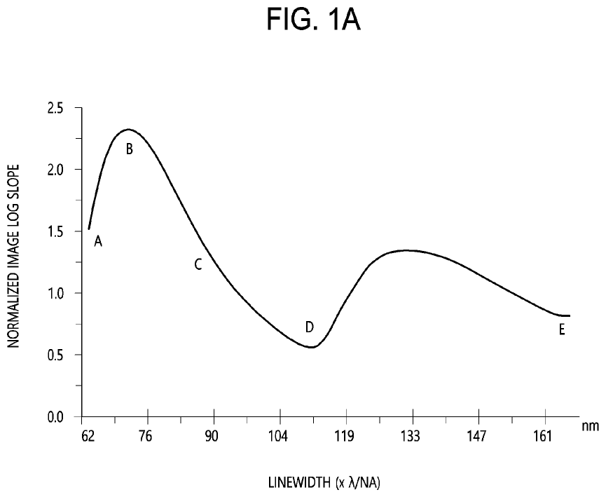

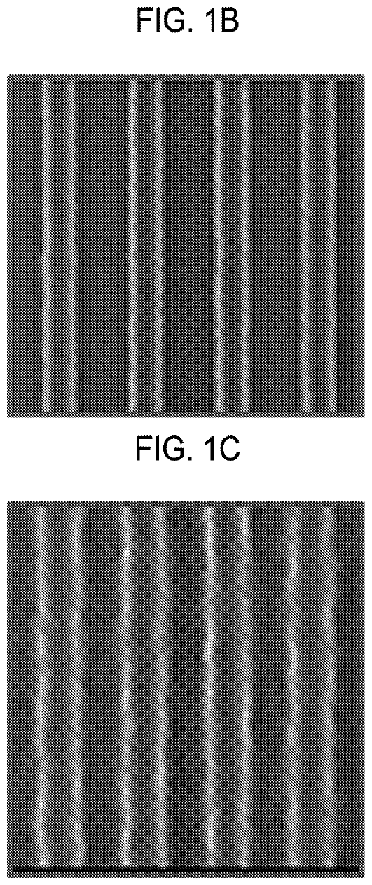

FIG. 1A through FIG. 1C are views illustrating patterns by target widths in an optical apparatus having a high resolution.

For example, a process for manufacturing a semiconductor integrated circuit may include a photolithography process. In the photolithography process, a circuit pattern of an exposure mask may be transcribed onto a photoresist film on a wafer using an illumination device.

A photoresist pattern formed by the photolithography process may be used as a mask for etching a layer under the photoresist pattern. A width of the photoresist pattern may correspond to a width of a target pattern formed from the layer. Thus, the width of the photoresist pattern may be an important factor for determining integration degree of the semiconductor device.

The target patterns are formed having a target width. In order to provide the target patterns, which may be repeatedly arranged in a same direction, for example, an X-direction, an optical apparatus including a variable illuminator such as a dipolar illuminator may be used. The target pattern having a width below about 80 nm may be formed using the variable illuminator.

FIG. 1A shows a normalized image log slope (NILS) by a target width (linewidth), FIG. 1B shows an image of a target pattern having a width of about 76 nm, and FIG. 1C shows an image of a target pattern having a width of about 160 nm.

The NILS may be a value obtained by normalizing an image using a slope and a width of the image. The image may be accurately made proportional to an increase in the normalized value.

The image of the target pattern having the width of about 76 nm formed using the variable illuminator is shown in FIG. 1B. The NILS of the target pattern may have good quality as indicated by B in FIG. 1A.

A target pattern having the width of about 160 nm may, however, have an abnormal or low-quality profile as indicated by E in FIG. 1A and shown in FIG. 1C.

This abnormal or low-quality profile may result from a forbidden pitch section problem caused by a deficiency of ±n^{th} diffracted light due to low exposure in the modified illuminator optimal to a fine pattern. In a fabrication environment optimal to the formation of a fine pattern, forming a pattern having a target pitch in a forbidden pitch section in accordance with a density difference of the patterns on the substrate may be advantageous.

The semiconductor device may be divided into a cell region and a peripheral region. The target pattern in the peripheral region may have a width wider than a width of the target pattern in the cell region. In order to form the target pattern using a single illuminator, the target pattern may include different widths in the cell region and the peripheral region, and an exposure mask may be utilized, where the exposure mask is capable of forming a pattern in the peripheral region having a width wider than a width of a pattern in the cell region.

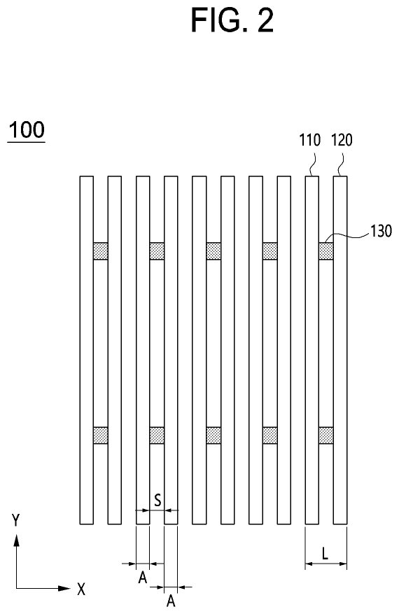

FIG. 2 is a view illustrating an exposure mask in accordance with example embodiments.

Referring to FIG. 2, an exposure mask 100 may be utilized to form a target pattern having a first width L used as a line pattern.

The exposure mask 100 includes a first line 110, a second line 120 and at least one bridge line 130. The first line 110 may be extended in a first direction (Y-direction). The first line 110 has a second width A narrower than the first width L. The second line 120 may be extended parallel to and spaced apart from the first line 110. The second line 120 may have the second width A. The bridge line 130 is connected between the first line 110 and the second line 120. A line group including the first line 110, the second line 120, and the bridge line 130 may collectively be repeatedly arranged at a set interval in a second direction (X-direction) in the exposure mask. Each of the repeated line groups is separated from the next closest line group by a gap, which gap may advantageously be the same gap between successive line groups. The line group or line pattern is formed having a first width L. A gap S between the first line 110 and the second line 120 may be wider than the second width A.

The semiconductor device may have a first region and a second region. The first region corresponds to the cell region. The second region corresponds to the peripheral region. A first target pattern having the second width A is formed in the first region. A second target pattern having the first width is formed in the second region.

The exposure mask 100 in FIG. 2 may be utilized to form the second target pattern having the first width in the second region.

In example embodiments, the second width A may be less than half of the first width. For example, when the first width L is about 130 nm to about 170 nm, the second width A may be about 65 nm to about 85 nm, but not limited thereto. The gap S between the first line 110 and the second line 120 may be wider by about 10 nm than the second width A, but not limited thereto.

An image including the first line 110, the second line 120, and the bridge line 130 having the second width A may be transcribed onto a photoresist film using the modified illuminator to form a photoresist pattern. A layer may be patterned using the photoresist pattern as an etch mask to form a pattern having good quality profile.

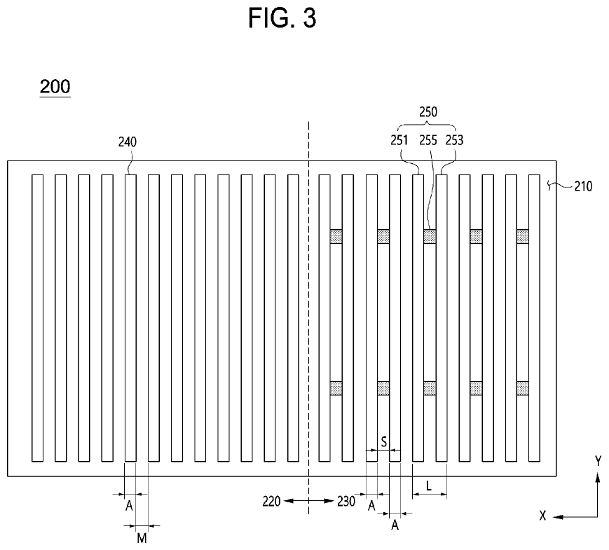

FIG. 3 is a plan view illustrating a semiconductor device in accordance with example embodiments.

Referring to FIG. 3, a semiconductor device 200 of example embodiments includes a semiconductor substrate 210, first target patterns 240, and second target patterns 250. A first region 220 and a second region 230 are included on the semiconductor substrate 210 in the example of FIG. 3. The first target patterns 240 are formed in the first region 220. The second target patterns 250 are formed in the second region 230.

The first target patterns 240 may be extended in the first direction (Y-direction). Each of the first target patterns 240 are formed with the second width A. A plurality of the first target patterns 240 are spaced apart from each other by a distance M along the second direction (X-direction). The first target patterns 240 are shown parallel to and spaced apart from each other in the example of FIG. 3.

The second target patterns 250 are formed having the first width L wider than the second width A. The second target pattern 250 includes a first line 251, a second line 253, and at least one bridge line 255.

The first line 251 may be extended in the first direction. The first line 251 is formed having the second width A. The second line 253 is spaced apart from the first line 251 by the distance S along the second direction. The second line 253 may be extended in the first direction. The second line 253 is formed having the second width A. One or more bridge lines 255 are connected between the first line 251 and the second line 253.

In example embodiments, one of a plurality of contacts 320 is formed under each of the bridge lines 255. Thus, each of the bridge lines is formed at a position corresponding to a position of one of the plurality of contacts. The contacts 320 may be arranged in the first direction. In this example, the bridge lines 255 contact upper or first surfaces of the contacts 320. The second target patterns 250 are electrically connected by the contacts.

According to example embodiments, the first line 251 and the second line 253 in the second region 230 are formed having the second width A. The bridge line 255 is connected between the first line 251 and the second line 253. Thus, the second target pattern 250 is a target pattern having the first width L. The first width L may be, for example, at least 2A.

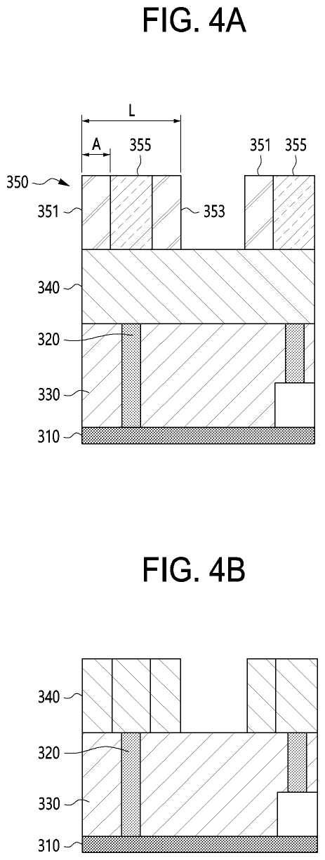

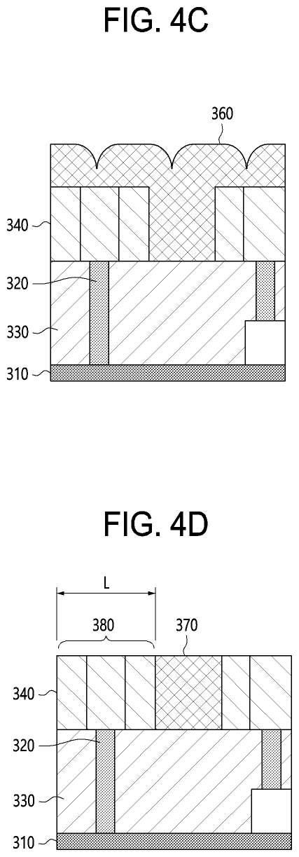

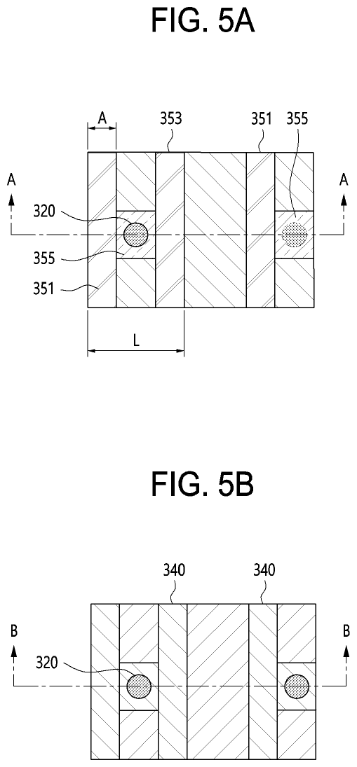

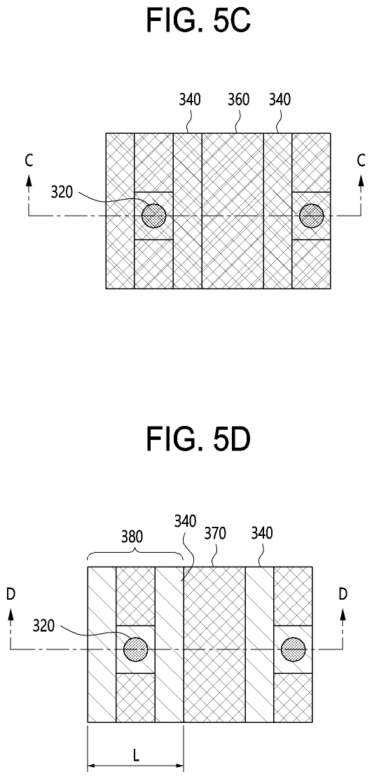

FIG. 4A through FIG. 4D illustrate cross-sectional views of a semiconductor device formed utilizing a method of manufacturing the semiconductor device in accordance with example embodiments. FIG. 5A through FIG. 5D illustrate plan views of a semiconductor device formed utilizing a method of manufacturing the semiconductor device in accordance with example embodiments.

In more detail, FIG. 4A through FIG. 4D are cross-sectional views through FIG. 5A through FIG. 5D, respectively, illustrating a second region of a semiconductor device on a semiconductor substrate on which the first region (cell region) and the second region (peripheral region) are disposed. FIG. 5A through FIG. 5D are plan views illustrating the second region. The cross-hatching in FIG. 4A through FIG. 4D and FIG. 5A through FIG. 5D illustrates corresponding or similar areas between the figures rather than indicating the materials for the areas.

Although not depicted in drawings, patterns may be repeatedly arranged at a set or fixed interval in the first region of the semiconductor substrate along the second direction. The patterns having the second width may be extended in the first direction.

Referring to FIG. 4A that is a cross-section through line A-A in FIG. 5A, a photoresist pattern 350 may be formed on a semiconductor substrate 310 with lower structures 320, 330, and 340.

The lower structures 320, 330, and 340 may be produced by forming at least one conductive layer 340 on at least one insulating interlayer 330 with at least one contact 320, and planarizing the conductive layer 340, but not limited thereto. The lower structures 320, 330, and 340, may include other structures formed, for example, by a dual damascene process.

The photoresist pattern 350 may be formed using the exposure mask 100 of FIG. 2. The photoresist pattern 350 includes a first line 351, a second line 353, and at least one bridge line 355, the lines 351, 353, and 355 collectively having a width L. The first line 351 is extended in the first direction. The first line 351 is formed having the second width A narrower than the first width L. The second line 353 is shown extended parallel to and spaced apart from the first line 351 in FIG. 5A in this example. The second line 353 is formed having the second width A. The bridge line 355 is connected between the first line 351 and the second line 353. The photoresist pattern 350 including the first line 351, the second line 353, and the bridge line 355 is repeatedly arranged in the second direction that is 90 degrees rotated with respect to the first direction in this example. The first line 351, the second line 353, and the bridge line 355 form a group that may advantageously be repeatedly arranged at a set or fixed interval, for example, having a uniform gap or space between successive groups. The bridge lines 355 may be configured to cover the upper or first surfaces of the contacts 320 arranged in the first direction.

Referring to FIG. 4B that is a cross-section through line B-B in FIG. 5B, the conductive layer 340 may be patterned using the photoresist pattern 350 as an etch mask.

Referring to FIG. 4C that is a cross-section through line C-C in FIG. 5C, an insulation layer 360 may be formed on the entire structure. The insulation layer 360 may then be planarized or removed, for example, above the uppermost surface of section 340 in FIG. 4C such that section 370 of the insulation layer 360 remains as shown in FIG. 4D and FIG. 5D. For example, the planarization process may continue until the conductive layer 340 is exposed. Target pattern 380 is formed having the first width L as shown in FIG. 4D and FIG. 5D. The first width L is at least two times or at least twice the second width A.

Therefore, the target pattern having a good quality profile is produced having the first width wider than the second width and may be formed using the optical apparatus configured to form the second width.

The above-described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. An exposure mask for forming a pattern having a first width, the exposure mask comprising:
a first line extended in a first direction, the first line having a second width narrower than the first width;
a second line extended parallel to and spaced apart from the first line, the second line having the second width; and
at least one bridge line connected between the first line and the second line.

2. The exposure mask of claim 1, wherein the first line, the second line, and the at least one bridge line comprise a line group that is repeatedly arranged at a set interval along a second direction different from the first direction.

3. The exposure mask of claim 1, wherein the first width is at least two times the second width.

4. A semiconductor device comprising:
a semiconductor substrate having a first region and a second region;
a first target pattern formed in the first region and extended in a first direction, the first target pattern having a second width; and
a second target pattern formed in the second region, the second target pattern formed having a first width wider than the second width;
wherein the second target pattern comprises:
a first line extended in the first direction, the first line having the second width;
a second line spaced apart from the first line along a second direction different from the first direction and extended in the first direction, the second line having the second width; and
at least one bridge line connected between the first line and the second line.

5. The semiconductor device of claim 4, wherein the first target pattern is repeatedly arranged and separated by a gap along the second direction.

6. The semiconductor device of claim 4, further comprising a contact having a surface in contact with at least one bridge line.

7. The semiconductor device of claim 4, wherein the second target pattern is repeatedly arranged and separated by a gap along the second direction.

8. A semiconductor device comprising:
a lower structure including a plurality of contacts arranged in a first direction;
a first line extended along a first side of the contacts over the lower structure in the first direction, the first line having the second width;
a second line extended along a second side of the contacts over the lower structure in the first direction, the second line having the second width, wherein the first side of the contacts is located opposite to the second side of the contacts; and
a plurality of bridges line contacting first surfaces of the contacts thereby connecting the first line with the second line.

9. The semiconductor device of claim 8, wherein the first line, the second line, and the bridge lines are collectively formed having a first width wider than the second width.

10. The semiconductor device of claim 9, wherein the first width is at least two times the second width.

11. A method of manufacturing a semiconductor device, the method comprising:
providing a semiconductor substrate comprising a first region and a second region, the semiconductor substrate including a lower structure;
forming a first target pattern on the lower structure in the first region, the first target pattern having a second width narrower than a first width;
forming a photoresist pattern on the lower structure in the second region using an exposure mask, the exposure mask including a first line extended in the first direction and having the second width, a second line extended parallel to and spaced apart from the first line and having the second width, and at least one bridge line connected between the first line and the second line; and
patterning a layer of the lower structure under the photoresist pattern using the photoresist pattern to form a second target pattern having the first width.

12. The method of claim 11, wherein the lower structure comprises at least one contact arranged in the first direction, wherein the bridge line is formed at a position corresponding to a position of the contact.

13. The method of claim 11, wherein the first width is at least two times the second width.

14. The method of claim 11, further comprising forming an insulation layer on the lower structure and removing the insulation layer until the lower structure is exposed.

15. A semiconductor device comprising:
a semiconductor substrate comprising a first region and a second region:
a first target pattern is formed having a first width in the first region; and
a plurality of spaced second target patterns formed in the second region, wherein each second target pattern is formed having a second width and comprises:
a first line extended in a first direction;
a second line spaced apart from the first line along a second direction different from the first direction; and
at least one bridge line connected between the first line and the second line.

16. The semiconductor device of claim 15, where the second target patterns are formed utilizing a photoresist pattern.
